(19) United States
(12) Patent Application Publication
(10) Pub. No.: US 2003/0201789 A1
(43) Pub. Date: Oct. 30, 2003

(54) Bus termination system and method

(76) Inventors: John Edward Tillema, Fort Collins, CO (US); Dave John Marshall, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/131,988

(22) Filed: Apr. 25, 2002

(51) Int. Cl. H03K 19/003

(52) U.S. Cl. 326/30

(57) ABSTRACT

The present invention generally pertains to a system and method for terminating a communication bus, such as a communication bus interconnecting multiple integrated circuit (IC) chips. An integrated circuit (IC) chip in accordance with one embodiment of the present invention utilizes a bus termination and logic. The bus termination is coupled to the communication bus. The logic is configured to prevent the bus termination from terminating the communication bus when the IC chip is communicating a particular binary level to another IC chip. The logic is further configured to cause the bus termination to terminate the communication bus when the IC chip is communicating a different binary level to another IC chip.

### BACKGROUND OF THE INVENTION

1. Field of the Invention

The present invention generally relates to data communication techniques and, in particular, to a system and method for terminating a bus.

2. Related Art

Integrated circuits (ICs) are normally contained in a structure referred to as an “IC chip.” In practice, multiple IC chips are often attached to a printed circuit board (PCB) having one or more conductive buses extending to various IC chips in order to enable communication between the IC chips. Each such bus is normally terminated via pull-up and/or pull-down resistors located at opposite ends of the bus. These pull-up resistors may be located within the IC chips connected to the bus or may be located on the PCB (i.e., external to the IC chips).

It is generally desirable to increase the speed and reliability of the communication that occurs on buses interconnecting IC chips. Indeed, various techniques have been developed for improving the performance and accuracy of the communication between IC chips residing on PCBs. However, further improvements in such techniques are generally desirable.

### SUMMARY OF THE INVENTION

Generally, the present invention provides a system and method for terminating a communication bus.

An integrated circuit (IC) chip in accordance with one embodiment of the present invention utilizes a bus termination and logic. The bus termination is coupled to the communication bus. The logic is configured to prevent the bus termination from terminating the communication bus when the IC chip is communicating a particular binary level to another IC chip. The logic is further configured to cause the bus termination to terminate the communication bus when the IC chip is communicating a different binary level to another IC chip.

The present invention can also be viewed as providing a method for terminating communication buses. The method can be broadly conceptualized by the following steps: determining, in a first determination, that an integrated circuit (IC) chip is to communicate a particular binary level over a communication bus, determining, in a second determination, that the IC chip is to communicate a different binary level over the communication bus, enabling a bus termination in response to the first determination, the bus termination residing in the IC chip and coupled to the communication bus, and disabling the bus termination in response to the second determination.

### BRIEF DESCRIPTION OF THE DRAWINGS

The invention can be better understood with reference to the following drawings. The elements of the drawings are not necessarily to scale relative to each other, emphasis instead being placed upon clearly illustrating the principles of the invention. Furthermore, like reference numerals designate corresponding parts throughout the several views.

FIG. 1 is a block diagram illustrating a conventional integrated circuit (IC) system.

FIG. 2 is a diagram illustrating a more detailed view of bus terminations depicted in FIG. 1.

FIG. 3 is a diagram illustrating a circuitry configuration of two IC chips in FIG. 1 when one of the IC chips is communicating an electrical high to the other IC chip.

FIG. 4 is a diagram illustrating a circuitry configuration of two IC chips in FIG. 1 when one of the IC chips is communicating an electrical low to the other IC chip.

FIG. 5 is a diagram illustrating an IC system in accordance with an exemplary embodiment of the present invention.

FIG. 6 is a diagram illustrating a more detailed view of bus terminations depicted in FIG. 5.

FIG. 7 is a diagram illustrating a circuitry configuration of two IC chips in FIG. 5 when one of the IC chips is communicating an electrical high to the other IC chip.

FIG. 8 is a diagram illustrating a circuitry configuration of two IC chips in FIG. 5 when one of the IC chips is communicating an electrical low to the other IC chip.

FIG. 9 is a flow chart illustrating an example architecture and functionality of control logic for one of the IC chips depicted in FIG. 5.

### DETAILED DESCRIPTION OF THE PREFERRED EMBODIMENT

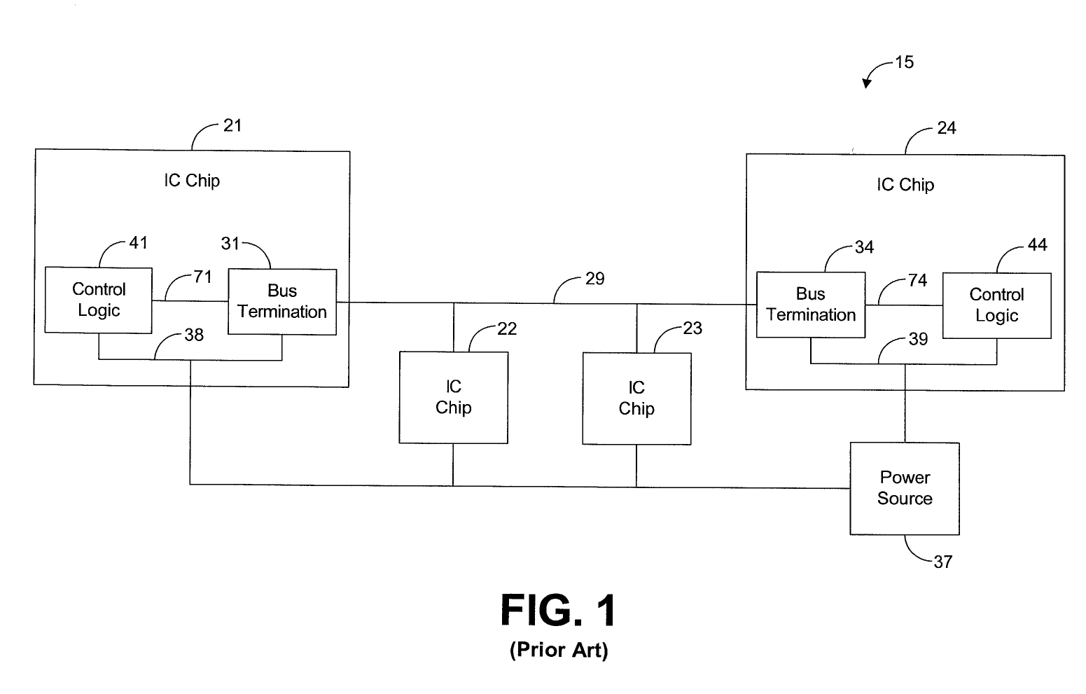

FIG. 1 depicts a conventional integrated circuit (IC) system 15 including multiple IC chips 21-24 capable of communicating to one another over a conductive bus 29. Each of the IC chips 21-24 and the bus 29 may reside on a printed circuit board (not specifically shown) and may receive electrical power from a power source 37 that may also reside on the printed circuit board (PCB). Each of the IC chips 21-24 normally includes a power bus for providing power received from the power source 37 to different components of the IC chip 21-24. As an example, IC chip 21 includes a power bus 38 for delivering power from the power source 37 to one or more components of the IC chip 21, and the IC chip 24 includes a power bus 39 for delivering power from the power source 37 to one or more components of the IC chip 24.

As shown by FIG. 1, the bus 29 is terminated via a pair of bus terminations 31 and 34 residing within the IC chips 21 and 24, respectively. As known in the art, when a bus termination terminates an end of a bus, the bus termination generally prevents or significantly reduces reflections from propagating over the bus from the bus end. Note that one or more of the terminations 31 and 34 may reside external to the IC chips 21-24 (e.g., may reside directly on the PCB), if desired. When terminations 31 and 34 reside in the IC chips 21 and 24, as shown by FIG. 1, control logic 41 and 44 within the IC chips 21 and 24, respectively, may generally control the configuration and operation of the terminations 31 and 34 according to techniques that will be described in more detail below. It should be noted that IC chips 22 and 23 do not typically terminate the bus 29.

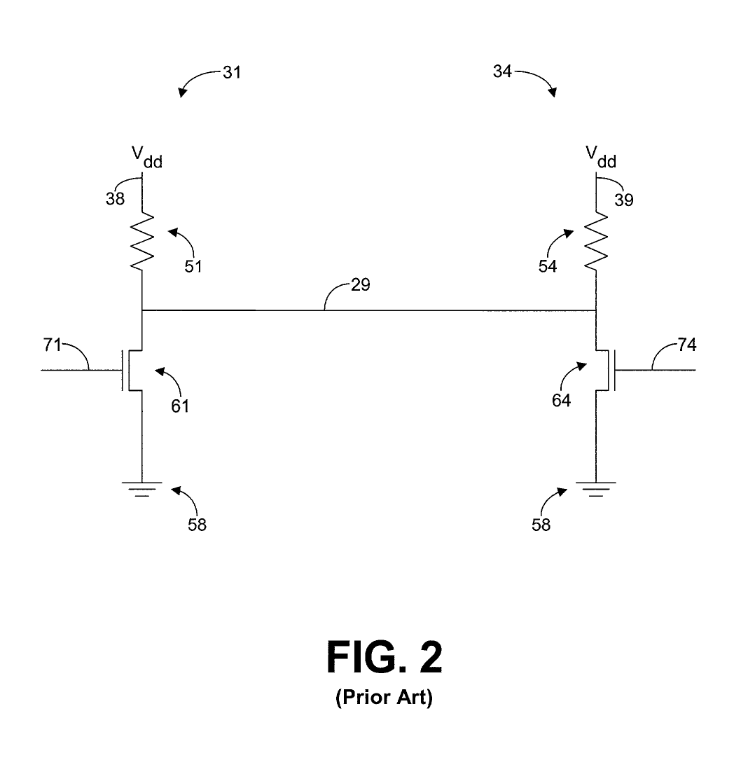

FIG. 2 depicts a more detailed view of the terminations 31 and 34 of the IC chips 21 and 24. As shown by FIG. 2, each termination 31 and 34 includes a pull-up resistor 51 or 54, referred to hereafter as “termination resistor.” One end of each termination resistor 51 and 54 is conductively coupled to its chip's power bus 38 or 39, which exhibits a voltage (V_{dd}) based on the power delivered by the power source 37 (FIG. 1). The opposite end of each termination resistor 51 and 54 is conductively coupled to the bus 29. This opposite end of each termination resistor 51 and 54 is also conductively coupled to ground 58 through a transistor 61 or 64, as shown by FIG. 2. The transistor 61 of the IC chip 21 receives a control signal from the control logic 41 (FIG. 1) via connection 71, and the transistor 64 of the IC chip 24 receives a control signal from the control logic 44 via connection 74.

When the IC chip 24 is not transmitting, the control logic 44 deactivates the transistor 64. As used herein, a transistor is “deactivated” when it is provided a control signal that causes the transistor to effectively operate as an open circuit, and a transistor is “activated” when it is provided with a control signal that causes the transistor to effectively operate as a short circuit. Thus, when the IC chip 24 is not transmitting, the control logic 44 controls the transistor 64 such that the transistor 64 effectively operates as an open circuit, thereby electrically separating the termination resistor 54 and the bus 29 from the ground 58 within chip 24. Deactivating the transistor 64 prevents the IC chip 24 from grounding the bus 29 while one of the other chips 21-23 is transmitting across the bus 29.

When the IC chip 24 is to transmit an electrical high, the control logic 44 deactivates the transistor 64. As a result, the termination transistor 54 is electrically separated from the ground 58 within the chip 24. Deactivating the transistor 54 causes the IC chip 24 to drive a voltage close to V_{dd} across the bus 29. By driving this voltage across the bus 29, the IC chip 24 effectively transmits an electrical high to one of the other chips 21-23 connected to the bus 29.

When the IC chip 24 is to transmit an electrical low, the control logic 44 activates the transistor 64. In other words, the control logic 44 controls the transistor 64 such that the transistor 64 effectively operates as a short circuit, thereby electrically coupling the termination resistor 54 and the bus 29 to ground 58. Activating the transistor 64 causes the IC chip 24 to ground the bus 29. By grounding the bus 29, the IC chip 24 effectively transmits an electrical low to one of the other chips 21-23 connected to the bus 29.

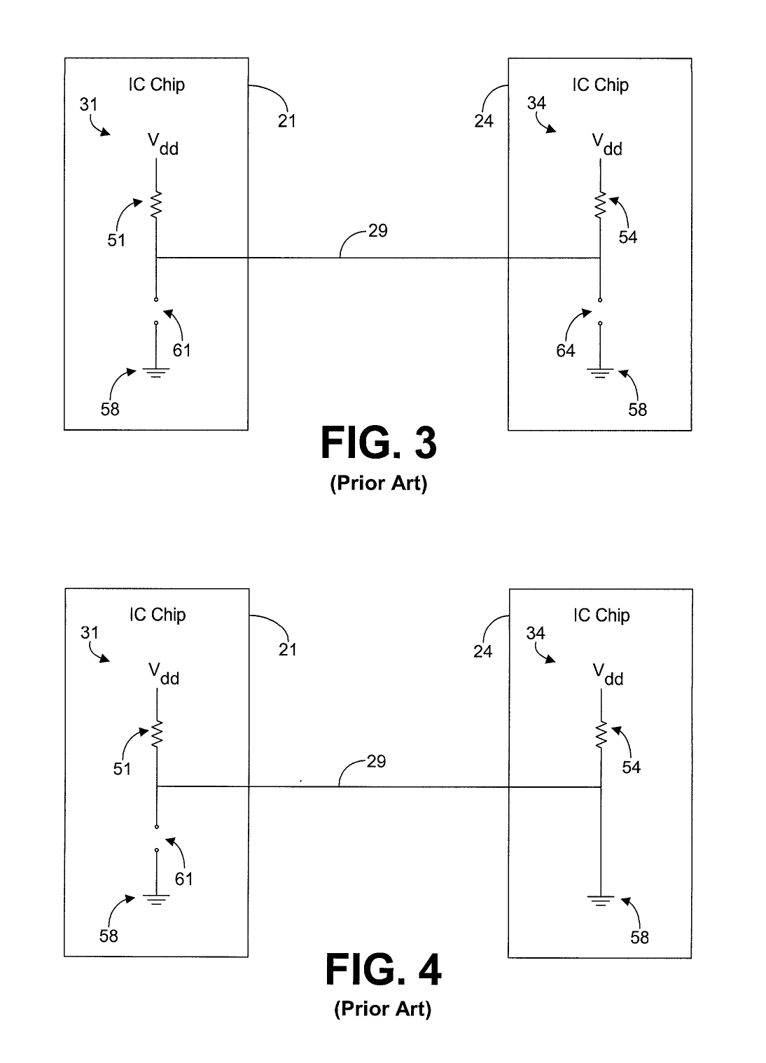

The control logic 41 of the IC chip 21 controls the termination 31 in the same way that control logic 44 controls the termination 34. Therefore, when the IC chip 24 is transmitting an electrical high, the circuitry configuration of the terminations 31 and 34 of IC chips 21 and 24 is generally shown by FIG. 3. Furthermore, when the IC chip 24 is transmitting an electrical low, the circuitry configuration of the terminations 31 and 34 of IC chips 21 and 24 is generally shown by FIG. 4.

Note that to prevent data errors, it is normally desirable for only one IC chip 21-24 to transmit across the bus 29 at a time. Furthermore, there are a variety of well-known protocols, sometimes referred to as “arbitration protocols,” for controlling which of the IC chips 21-24 is authorized to communicate over the bus 29. The rules of these protocols normally authorize only one IC chip 21-24 to transmit over the bus 29 at any given time. By implementing and following such protocols, attempts by multiple IC chips 21-24 to simultaneously transmit information over the bus 29 are generally prevented.

In some situations, it is possible for conductive and capacitive resonance within the IC chips 21 and/or 24, when coupled with fluctuations within the chips 21 and/or 24, to cause the power signals appearing on power buses 38 and/or 39 to oscillate. This oscillation of the power signals can cause delays and/or data corruption within the IC chips 21 and/or 24. Moreover, in order to improve performance of the IC chips 21 and/or 24, it is generally desirable to reduce any oscillation that occurs in the chips' power signals.

It has been discovered that the aforementioned oscillation, referred to hereafter as “power signal oscillation,” for a chip 21 or 24 is generally exacerbated by fluctuations in current drawn through the chip's bus termination 31 or 34. As an example, transitioning between the states shown by FIGS. 3 and 4 induces current to be intermittently drawn between the power bus 39 (FIG. 2) and ground 58 through termination resistor 54 and, therefore, causes power signal oscillation within the chip 24. Moreover, it has been concluded that the power signal oscillation in one of the chips 21 or 24 can be reduced by preventing or reducing fluctuations in the current that flows between the chip's power bus 38 or 39 to ground 58 via the chip's termination resistor 51 or 54.

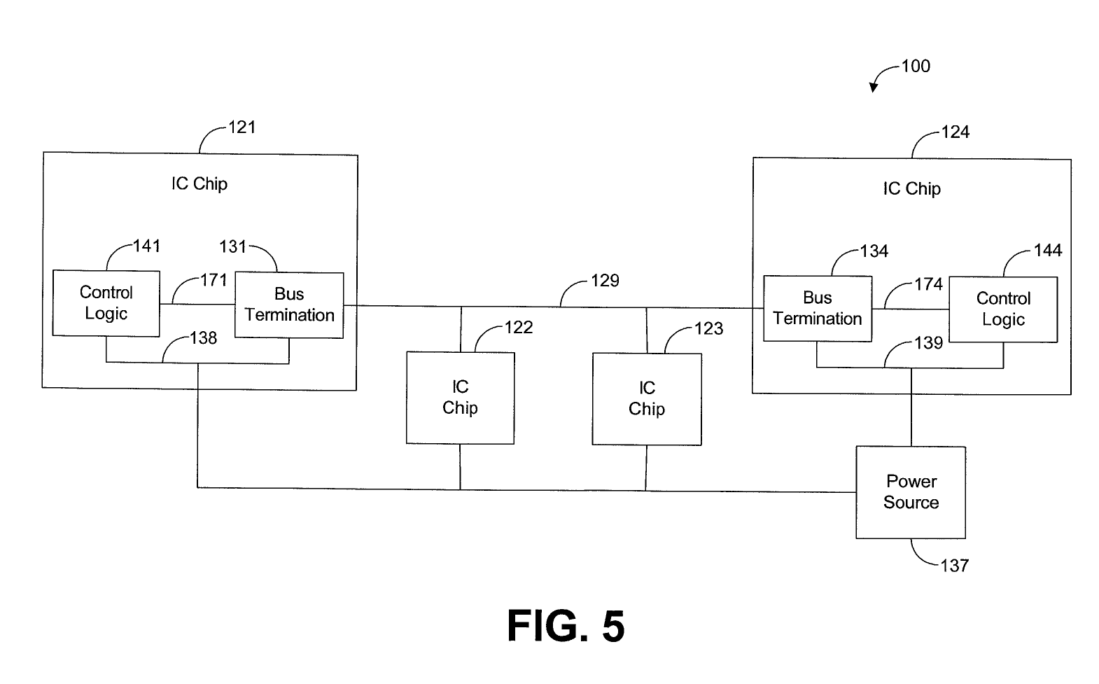

The present invention generally pertains to an IC system and method for terminating a communication bus between multiple IC chips such that power signal oscillation in at least one of the IC chips is reduced. FIG. 5 depicts an IC system 100 in accordance with a preferred embodiment of the present invention. As shown by FIG. 5, the system 100 includes multiple IC chips 121-124 that may communicate to one another over a conductive bus 129. Note that the bus 129 shown by FIG. 5 is an open drain bus in accordance with Gunning Transceiver Logic (GTL) standards. If desired, the termination techniques described herein may be employed for other types of buses. Furthermore, four IC chips 121-124 are shown for illustrative purposes, and other numbers of IC chips 121-124 may be employed in other embodiments.

Each of the IC chips 121-124 and the bus 129 may reside on a printed circuit board (not specifically shown) and may receive electrical power from a power source 137 that may also reside on the printed circuit board (PCB). Furthermore, each of the IC chips 121-124 preferably includes a power bus for providing power received from the power source 137 to different components of the IC chips 121-124. As an example, the IC chip 121 includes a power bus 138 for delivering power from the power source 137 to one or more components of the IC chip 121, and the IC chip 124 includes a power bus 139 for delivering power from the power source 137 to one or more components of the IC chip 124.

As shown by FIG. 5, the bus 129 is terminated via a pair of terminations 131 and 134 residing within the IC chips 121 and 124, respectively. Note that one or more of the terminations 131 and 134 may reside external to the IC chips 121-124 (e.g., may reside on the PCB). When residing in the IC chips 121 and 124, as shown by FIG. 5, control logic 141 and 144 within the IC chips 121 and 124, respectively, may generally control the configuration and operation of the terminations 131 and 134 according to techniques that will be described in more detail below. It should be noted that the control logic 141 and 144 are preferably implemented in hardware in order to enhance the speed at which the logic 141 and 144 operate. However, in other embodiments, the logic 141 and/or 144 may be implemented in software or a combination of hardware and software. Furthermore, the IC chips 121-124 may implement any known arbitration protocol in order to prevent multiple ones of the IC chips 21-24 from attempting to simultaneously communicate over the bus 129.

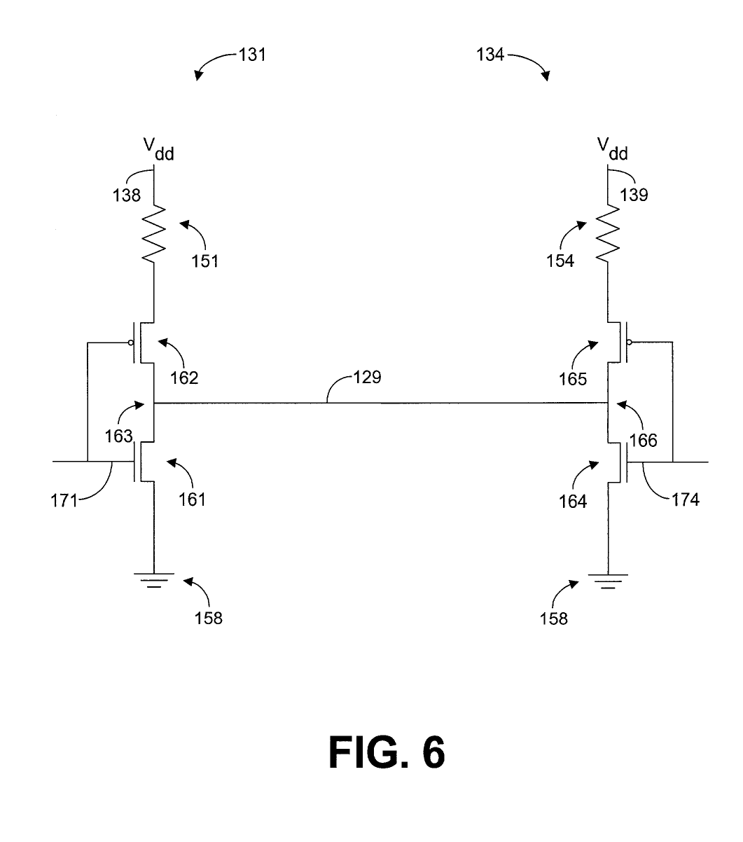

FIG. 6 depicts a more detailed view of the terminations 131 and 134 of the IC chips 121 and 124. As shown by FIG. 6, each termination 131 and 134 comprises a pull-up resistor 151 or 154, referred to hereafter as “termination resistor.” One end of each termination resistor 151 and 154 is conductively coupled to its chip's power bus 138 or 139, which exhibits a voltage (V_{dd}) based on the power delivered by the power source 137. The opposite end of each termination resistor 151 and 154 is conductively coupled to switching devices 162 and 165, respectively. Switching devices 162 and 165 are respectively coupled to switching devices 161 and 164 as well as bus 129, and each of the switching devices 161 and 164 is coupled to ground 158, as shown by FIG. 6. Note that each of the switching devices 161, 162, 164, and 165 comprises a transistor in the preferred embodiment and will be referred to as such hereafter.

Moreover, the termination resistor 151 of termination 131 is coupled to ground 158 through a series of transistors 161 and 162 with the bus 129 coupled to a node 163 between the two transistors 161 and 162. Each of the transistors 161 and 162 receives a control signal from the control logic 141 via connection 171. However, the input to the transistor 162 is preferably inverted relative to the input of the transistor 161. Therefore, when the transistor 161 is activated, the transistor 162 is preferably deactivated, and when the transistor 161 is deactivated, the transistor 162 is preferably activated.

Furthermore, the termination resistor 154 of termination 134 is coupled to ground 158 through a series of transistors 164 and 165 with the bus 129 coupled to a node 166 between the two transistors 164 and 165. Each of the transistors 164 and 165 receives a control signal from the control logic 144 via connection 174. However, the input to the transistor 165 is preferably inverted relative to the input of the transistor 164. Therefore, when the transistor 164 is activated, the transistor 165 is preferably deactivated, and when the transistor 164 is deactivated, the transistor 165 is preferably activated.

When the IC chip 124 is not authorized to transmit, the control logic 144 preferably deactivates the transistor 164 and, therefore, activates the transistor 165. As a result, the transistor 164 effectively operates as an open circuit, thereby electrically separating the termination resistor 154 and the bus 129 from the ground 158 within the IC chip 124. Deactivating the transistor 164 prevents the IC chip 124 from grounding the bus 129 while one of the other chips 121-123 is transmitting across the bus 129.

When the IC chip 124 is to transmit an electrical high, the control logic 144 deactivates the transistor 164 and, therefore, activates the transistor 165. As a result, the transistor 164 effectively operates as an open circuit, thereby electrically separating the termination resistor 154 and the bus 129 from the ground 158 within the IC chip 124. Deactivating the transistor 164 causes the IC chip 124 to drive a voltage close to V_{dd} across the bus 129. By driving this voltage across the bus 129, the IC chip 124 effectively transmits an electrical high to one of the other chips 121-123 connected to the bus 129.

When the IC chip 124 is to transmit an electrical low, the control logic 144 activates the transistor 164 and, therefore, deactivates the transistor 165. As a result, the transistor 164 effectively operates as a short circuit, thereby electrically coupling the bus 129 to the ground 158 within the IC chip 124. Furthermore, the transistor 165 effectively operates as an open circuit, thereby electrically separating the termination resistor 154 from the ground 158 within the IC chip 124. Moreover, activating the transistor 164 causes the IC chip 124 to ground the bus 129. By grounding the bus 29, the IC chip 124 effectively transmits an electrical low to one of the other chips 121-123 connected to the bus 129.

The control logic 141 of the IC chip 121 preferably controls the termination 131 in the same way that control logic 144 controls the termination 134. In this regard, the control logic 141 preferably deactivates the transistor 161 and activates the transistor 162 when the IC chip 121 is not authorized to transmit or is to transmit an electrical high. Furthermore, the control logic 141 preferably activates the transistor 161 and deactivates the transistor 162 when the IC chip 121 is to transmit an electrical low.

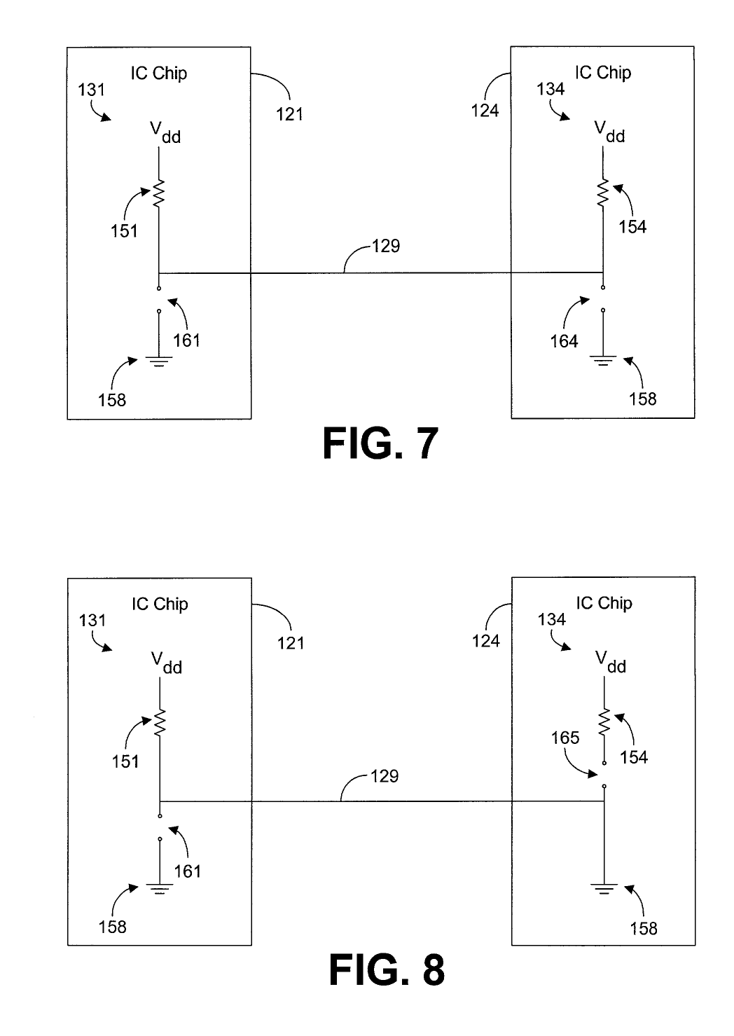

Accordingly, when the IC chip 124 is transmitting an electrical high, the circuitry configuration of the terminations 131 and 134 of the IC chips 121 and 124 is generally shown by FIG. 7. Furthermore, when the IC chip 124 is transmitting an electrical low, the circuitry configuration of the terminations 131 and 134 of the IC chips 121 and 124 is generally shown by FIG. 8.

Moreover, unlike the IC chip 24 in the conventional IC system 15, the IC chip 124 in the preferred embodiment fails to terminate the bus 129 when it is driving an electrical low, as shown by FIG. 8. In this regard, the transistor 165 effectively operates as an open circuit when the IC chip 124 is transmitting or, in other words, driving an electrical low, thereby separating the termination resistor 154 and, therefore, the power bus 139 (FIG. 5) from the bus 129. As a result, current is prevented from flowing between the buses 129 and 139 through the termination resistor 154, and the termination resistor 154 is effectively removed from the circuit shown by FIG. 8. It can be appreciated by one of ordinary skill in the art that preventing current from flowing through the termination resistor 154 disables the bus termination 134 or, in other words, prevents the bus termination 134 from terminating the bus 129.

Preventing the bus termination 134 from terminating the bus 129 when the IC chip 124 is communicating an electrical low, as described above, generally reduces the power signal oscillation that occurs in the IC chip 124. In this regard, as previously described, inductive and capacitive resonance within the IC chip 124 may cause the power signal of the power bus 139 to oscillate in response to current fluctuations occurring within the IC chip 124. Moreover, preventing or reducing current fluctuations through the termination resistor 54 generally helps to reduce the effect of the foregoing resonance on the power signal. Thus, if the termination 134 is disabled when the chip is transmitting an electrical low, as shown by FIG. 8, then current is prevented from flowing between the power bus 139 (FIG. 5) and ground 158 through the termination resistor 154 in both of the states shown by FIGS. 7 and 8. As a result, current fluctuations through the termination resistor 154 are reduced or prevented as the chip 124 transitions between the states shown by FIGS. 7 and 8, thereby reducing the power signal oscillation that occurs within the IC chip 124.

In addition, similarly configuring IC chip 121 to deactivate the transistor 162 when it is transmitting an electrical low can reduce the maximum current transmitted over bus 129. In this regard, similarly configuring the IC chip 121 ensures that at least one of the termination resistors 151 or 154 is electrically separated from the bus 129 when one of the IC chips 121 or 124 is transmitting an electrical low (i.e., when one of the IC chips 121 or 124 grounds the bus 129). Separating one of the termination resistors 151 or 154 from the bus 129 increases the effective resistance of the bus 129, thereby decreasing the amount of current passing over the bus 129. As a result, the transistors 161, 162, 164, and/or 165 can meet lower current requirements, and transistors meeting lower current requirements can usually be manufactured smaller and with less expense than transistors meeting higher current requirements. Furthermore, using smaller components within the IC chips 121-124 is generally desirable for reducing the circuitry size and/or complexity of the IC chips 121-124.

It should be noted that, if desired, the transistor 165 of FIG. 6 may be coupled to the termination resistor 154 on the opposite side of the termination resistor 154 (i.e., between the termination resistor 154 and V_{dd}) without departing from the principles of the present invention. In such an embodiment, the transistor 165 may be controlled via the same techniques and, therefore, may essentially operate the same as in the embodiment previously described above. Moreover, the same effects pertaining to the reduction of power signal oscillation and to the reduction in the maximum bus current can be realized regardless of which side of the termination resistor 154 the transistor 165 is located.

### OPERATION

The preferred use and operation of one of the IC chips 124 within the IC system 100 are described hereafter. Note that the same techniques described hereafter may be employed for operating IC chip 121.

In the preferred embodiment, the IC chips 121-124 preferably implement a known arbitration protocol for preventing multiple IC chips 121-124 from attempting to communicate across the bus 129 at the same time. According to such a protocol, only one IC chip 121-124 is authorized to communicate across the bus 129 at any given instant. Techniques for implementing such a protocol are well-known in the art and will not be described in further detail herein.

In block 202, the control logic 144 determines whether the IC chip 124 is authorized by the arbitration protocol to transmit across the bus 129. If the IC chip 124 is not authorized to communicate across the bus 129, the control logic 144 deactivates transistor 164 and activates transistor 165, as shown by block 205. As a result, the configuration of the termination 134 appears as shown by FIG. 7, and the IC chip 124, therefore, fails to ground the bus 129. Failing to ground the bus 129 enables one of the other IC chips 121-123 (i.e., the chip 121-123 authorized to communicate over the bus 129) to selectively drive the bus 129 high or low depending on the value of the data bit being communicated by the other IC chip 121-123. Note that activation of the transistor 165 enables the bus termination 134 to terminate the bus 129. Thus, during implementation of block 205, the bus 129 is preferably terminated by the bus termination 134.

However, if the control logic 144 determines, in block 202, that the IC chip 124 is authorized to communicate across the bus 129, the control logic 144 then determines, in block 208, whether the next data bit to be transmitted by the IC chip 124 corresponds to an electrical high or an electrical low. If the next data bit corresponds to an electrical high, then the control logic 144 deactivates the transistor 164 and activates the transistor 165, as shown by block 212. As a result, the configuration of the termination 134 appears as shown by FIG. 7, and the IC chip 124, therefore, fails to ground the bus 129.

Since the IC chip 121 of the other termination 131 is not authorized to transmit at this time, the other IC chip 121 also fails to ground the bus 129 when the control logic 144 of the IC chip 124 is implementing block 212. Accordingly, during implementation of block 212, the voltage of the bus 129 is preferably close to V_{dd} or, in other words, exhibits an electrical high. Therefore, by implementing block 212, the control logic 144 effectively causes the transmission of an electrical high across the bus 129.

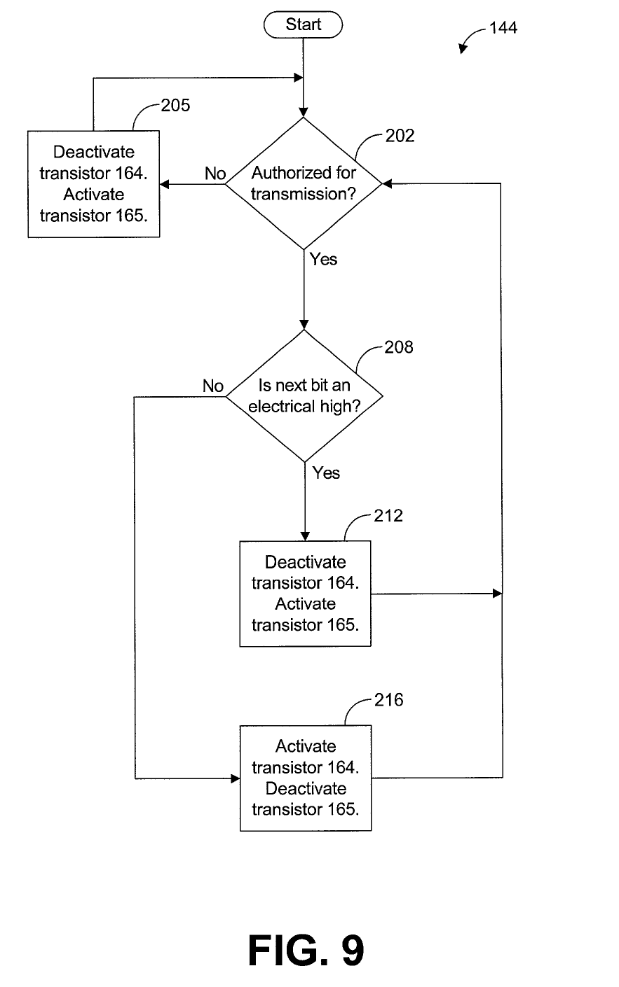

Note that the control logic 144 preferably implements block 212 (i.e., keeps the transistors 164 and 165 in the aforedescribed state) until the other IC chips 121-123 in the system 100 have been provided a sufficient opportunity for sensing the value transmitted via implementation of block 212. Once the other chips 121-123 have been provided such a sufficient opportunity, the control logic 144 proceeds to block 202, as shown by FIG. 9. It should be noted that, as described above, activation of the transistor 165 enables the bus termination 134 to terminate the bus 129. Thus, during the implementation of block 212, the bus 129 is preferably terminated by the bus termination 134.

If the control logic 144 determines, in block 208, that the next data bit to be transmitted by the IC chip 124 corresponds to an electrical low, then the control logic 144 activates the transistor 164 and deactivates the transistor 165, as shown by block 216. As a result, the configuration of the termination 134 appears as shown by FIG. 8, and the IC chip 124, therefore, grounds the bus 129. Accordingly, during implementation of block 216, the voltage of the bus 129 is preferably close to ground or, in other words, exhibits an electrical low. Therefore, by implementing block 216, the control logic 144 effectively causes the transmission of an electrical low across the bus 129.

Note that the control logic 144 preferably implements block 216 (i.e., keeps the transistors 164 and 165 in the aforedescribed state) until the other IC chips 121-123 in the system 100 have been provided a sufficient opportunity for sensing the value transmitted via implementation of block 216. Once the other chips 121-123 have been provided such a sufficient opportunity, the control logic 144 proceeds to block 202, as shown by FIG. 9.

It should be further noted that deactivation of the transistor 165 disables the bus termination 134 or, in other words, prevents the bus termination 134 from terminating the bus 129. Thus, during implementation of block 216, the bus 129 is preferably not terminated by the bus termination 134. Disabling the bus termination 134 during implementation of block 216 prevents or helps to reduce current fluctuations through the termination resistor 154 when the termination 134 transitions between the states shown by FIGS. 7 and 8. As a result, the amount of power signal oscillation occurring in the IC chip 124 is reduced.

Now, therefore, the following is claimed:

1. An integrated circuit (IC) chip, comprising:
a bus termination coupled to a communication bus; and
logic configured to prevent the bus termination from terminating the communication bus when the IC chip is communicating a particular binary level to another IC chip, the logic further configured to cause the bus termination to terminate the communication bus when the IC chip is communicating a different binary level to another IC chip.

2. The IC chip of claim 1, wherein the communication bus is an open drain bus.

3. The IC chip of claim 1, further comprising a power bus, and wherein the bus termination comprises:
a first switching element coupled to the power bus and to the communication bus along a conductive path that extends from the power bus to the communication bus,
wherein the logic is configured to prevent the bus termination from terminating the communication bus by deactivating the first switching element, and wherein deactivation of the first switching element electrically separates the power bus from ground.

4. The IC chip of claim 3, wherein the bus termination further comprises:
a second switching element coupled to the communication bus,
wherein the logic is configured to cause the IC chip to communicate the particular binary level by activating the second switching element and to cause the IC chip to communicate the different binary level by deactivating the second switching element.

5. The system of claim 4, wherein activation of the second switching element grounds the communication bus.

6. A system for terminating communication buses, comprising:
a communication bus;
a power bus;
a bus termination coupled to the communication bus, the bus termination having a first switching element and a second switching element, the first switching element coupled to the power bus and to the communication bus along a conductive path that extends from the power bus to the communication bus, the second switching element coupled to the communication bus; and
logic configured to communicate a particular binary level over the communication bus by activating the second switching element and to communicate a different binary level over the communication bus by deactivating the second switching element, the logic further configured to deactivate the first switching element if the second switching element is activated, wherein deactivation of the first switching element electrically separates the power bus from the communication bus.

7. The system of claim 6, wherein the communication bus is an open drain bus.

8. The system of claim 6, wherein the first and second switching elements are transistors.

9. The system of claim 6, wherein the switching elements and the logic reside within a single integrated circuit (IC) chip, and wherein the second switching element electrically couples the communication bus directly to ground when activated.

10. An integrated circuit (IC) chip interconnected to other IC chips via a communication bus, comprising:
means for terminating the communication bus; and
means for controlling the terminating means such that the terminating means terminates the communication bus in response to a determination that the IC chip is to communicate a particular binary level over the communication bus to another IC chip and such that the terminating means fails to terminate the communication bus in response to a determination that the IC chip is to transmit a different binary level over the communication bus to another IC chip.

11. The IC chip of claim 10, further comprising a means for providing power, wherein the terminating means comprises a switching element coupled to the providing means and the communication bus along a conductive path that extends from the providing means to the communication bus, and wherein the controlling means causes the switching element to electrically separate the power bus from the communication bus in response to the determination that the IC chip is to communicate the different binary level.

12. The IC chip of claim 10, wherein the controlling means is configured to control the terminating means such that the terminating means grounds the communication bus in response to the determination that the IC chip is to communicate the different binary level.

13. A method, comprising the steps of:
determining, in a first determination, that an integrated circuit (IC) chip is to communicate a particular binary level over a communication bus;
determining, in a second determination, that the IC chip is to communicate a different binary level over the communication bus;
enabling a bus termination in response to the first determination, the bus termination residing in the IC chip and coupled to the communication bus; and
disabling the bus termination in response to the second determination.

14. The method of claim 13, wherein the communication bus is an open drain bus.

15. The method of claim 13, further comprising the step of grounding the communication bus in response to the second determination.

16. The method of claim 13, further comprising the step of providing a power bus, wherein the disabling step prevents current from flowing between the power bus and the communication bus via the IC chip.

17. The method of claim 13, wherein the bus termination comprises a switching element coupled to the communication bus and to a power bus, and wherein the enabling step comprises the step of activating the switching element.

18. The method of claim 17, wherein the switching element is a transistor.

19. A method for terminating communication buses, comprising the steps of:
providing a plurality of IC chips interconnected via a communication bus;
communicating, over the communication bus, a particular binary level from one of the IC chips to another of the IC chips;
communicating, over the communication bus, a different binary level from the one IC chip to another of the IC chips;
terminating the communication bus, via the one IC chip, during the communicating a particular binary level step; and
preventing the one IC chip from terminating the communication bus during the communicating a different binary level step.

20. The method of claim 19, wherein the communication bus is an open drain bus.

21. The method of claim 19, wherein the communicating a different binary level step comprises the step of grounding the communication bus.

22. The method of claim 19, further comprising a power bus, wherein the preventing step prevents current from flowing between the power bus and the communication bus via the one IC chip.

23. The method of claim 19, wherein the one IC chip comprises a switching element coupled to the communication bus and the power bus, and wherein the preventing step comprises the step of changing an operational state of the switching element.
